(19) United States
(12) Patent Application Publication
(10) Pub. No.: US 2012/0166114 A1
(43) Pub. Date: Jun. 28, 2012

(54) SAVED POWER MEASURING CIRCUIT

(75) Inventor: YING-CHANG LIU, TAIPEI COUNTY (TW)

(73) Assignee: PRODIGIT ELECTRONICS CO., LTD., TAIPEI COUNTY (TW)

(21) Appl. No.: 13/159,528

(22) Filed: Jun. 14, 2011

(30) Foreign Application Priority Data
Dec. 28, 2010 (TW) 99146276

(51) Int. Cl. G01R 21/00; G06F 19/00

(52) U.S. Cl. 702/60

(57) ABSTRACT

A saved power measuring circuit comprises a control unit, a clock signal generating circuit connected to the control unit for generating a clock signal to the control unit, a power consumption measuring circuit connected to a power supply loop for measuring the power consumption of an electric appliance load operated in operation mode, a power consumption memory unit connected to the control unit for memorizing the power consumption, a break loop status signal generating circuit for generating a break loop status signal to the control unit. When the control unit receives the break loop status signal generated from the break loop status signal generating circuit, it calculates saved power of the electric appliance load in power saving mode according to the power consumption and the lasting time after receiving the break loop status signal.

### FIELD OF THE INVENTION

The present invention relates to a power measuring circuit, and in particular to a saved power measuring circuit.

### DESCRIPTION OF THE RELATED ART

In the electrical technology of prior art, if users want to know the information about power consumption of an electric appliance, a specific electric instrument or a traditional multi-meter is generally used for practically measuring. Taking home-used plug for example, a multi-meter or a voltmeter is usually used to measure voltage condition. First of all, users need to correctly adjust the meter to AC voltage status, and then carefully insert two probes into sockets to measure voltage condition. Another example is that if users want to know current value of a home-used steam cooker, usually another ampere meter (i.e. single-hook type meter) is needed for measuring current value. These measuring methods are only realizable for those who are familiar with electric engineering background knowledge or those who are electricians. But for general residents and workers unfamiliar with electric engineering, they have difficulty in doing these measurements. Furthermore, it's very hard for them to measure factors of electricity usage, such as power usage (KWHr), power factor, wattage, and etc.

In order to overcome these problems, the applicant had designed a measuring equipment to measure the electricity usage of electric appliance load in operation mode.

In prior art, standby functions are usually designed in home-used electric appliance loads due to that manufacturers usually consider the convenience of On/Off operation and the capability of quick turn-on function. As most electric appliance loads have standby functions, general users consider these electric appliance loads turned off when they are not used. But in fact these electric appliance loads still work in standby mode, and still consume energy. Although each electric appliance load consumes a few power in standby mode, the total power consumption of electric appliance loads in one house are relatively high.

To solve the problem of huge power consumption of electric appliance loads in standby mode, manufacturers had designed another power saving controller which can automatically turn off the power when electric appliance loads in standby mode, so as to switch off the connection between electric appliance loads and power supply for saving more power.

However, whether the power of electric appliance load is turned off by automatic power saving controller, user's manual operation or the other control signal, users still have no idea about how much power have been saved. With the requirement of energy saving and carbon dioxide reduction nowadays, although users understand the details of power measurement and power configuration of electric appliance loads in operation mode, they still can not understand the amount of saved power in power off mode and standby mode.

### SUMMARY OF THE INVENTION

Thus, an objective of the present invention is to provide a saved power measuring circuit, which is able to calculate saved power of the electric appliance load in power saving mode according to the power consumption and the operation time in operation mode.

To achieve this goal, the present invention provides a saved power measuring circuit for measuring saved power of an electric appliance load in power saving mode. A power consumption memory unit is connected to a control unit for memorizing the power consumption. A break loop status signal generating circuit generates a break loop status signal to the control unit. The control unit calculates saved power of the electric appliance load in power saving mode according to the power consumption and after receiving the break loop status signal generated from the break loop status signal generating circuit.

In another embodiment of the present invention, the break loop status signal generating circuit can be replaced with an operation signal generating circuit, which can generate a break loop status operation signals to the control unit, so as to turn on the switch unit connected to the power supply loop to be open loop. Hence, the control unit calculates saved power of the electric appliance load in power saving mode according to the power consumption and after receiving the break loop operation signal.

In efficient aspect, the present invention uses a simple circuit configuration to measure saved power of the electric appliance load in power saving mode, so that users can understand the accurate power consumption and saved power of the electric appliance load.

The embodiments described in the present invention will be further illustrated in the following examples and drawings.

### BRIEF DESCRIPTION OF THE DRAWINGS

FIG. 1 shows a circuit diagram of the first embodiment in the present invention;

FIG. 2 shows the illustration of electric appliance load operated in operation mode or power saving mode;

FIG. 3 shows a circuit diagram of the second embodiment in the present invention.

### DETAILED DESCRIPTION OF THE INVENTION

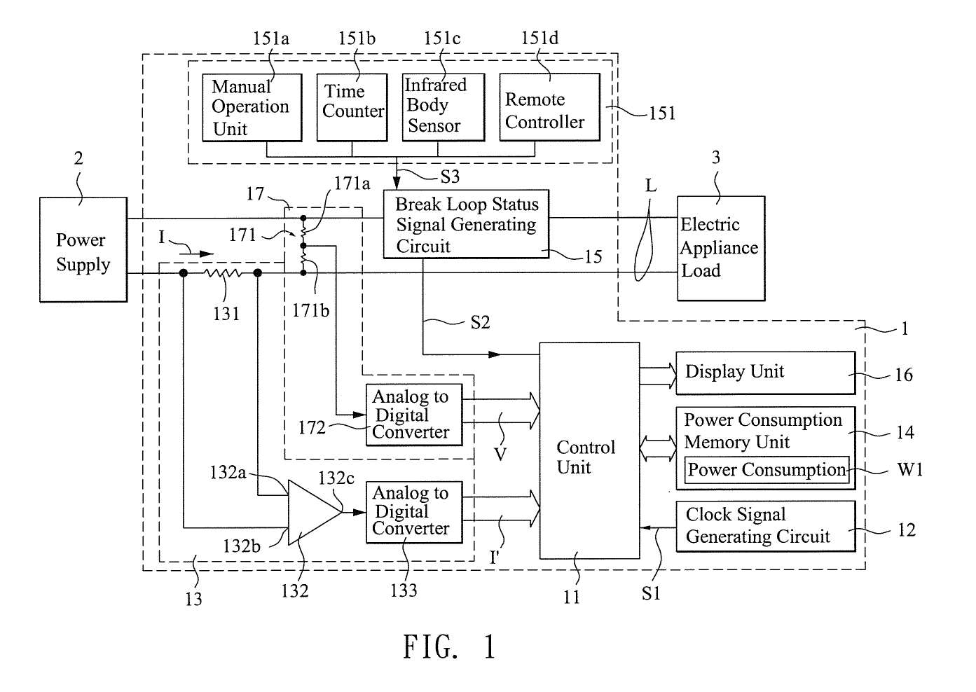

FIG. 1 shows a circuit diagram of the first embodiment in the present invention. The saved power measuring circuit 1 is connected between a power supply 2 and an electric appliance load 3, the saved power of the electric appliance load 3 switched from operation mode to power saving mode can be measured by the usage of the saved power measuring circuit 1 in the present invention.

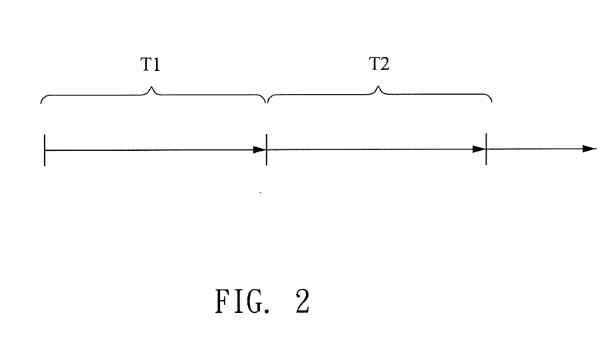

The electric appliance load 3 is connected to the power supply 2 through a power supply loop L. The electric appliance load 3 can be operated in operation mode T1 or power saving mode T2 (As shown in FIG. 2). The operation mode T1 defined in this specification includes the electric appliance load 3 in operation mode, such as in operation status, standby mode, and etc. When the electric appliance load 3 is operated in operation mode, it consumes power more than that in standby mode. The power saving mode T2 defined in this specification includes the electric appliance load 3 in non-operation mode, such as in break loop status, power saving status, and etc. When the electric appliance load 3 is operated in power saving mode T2, it doesn't consume any power.

The saved power measuring circuit 1 in the invention comprises a control unit 11, which is connected to a clock signal generating circuit 12 for generating a clock signal S1 to the control unit 11. The control unit 11 uses the clock signal S1 as a time counting basis.

A power consumption measuring circuit 13 is connected to the power supply loop L for measuring the current value I of electric appliance load 3 operated in operation mode T1 and transmitting the current value I to the control unit 11.

In this embodiment of the present invention, the power consumption measuring circuit 13 comprises a current sensor 131, which is connected in series to the power supply loop L. Two input terminals 132a, 132b of a current amplifier 132 are respectively connected to two terminals of the current sensor 131 for generating an analog current signal in an output terminal 132c of the current amplifier 132. An analog to digital converter 133 is connected to the output terminal 132c of the current amplifier 132 for receiving the analog current signal generated from the current amplifier 132 and transforming the analog current signal into digital type current value I′, and transmitting the digital type current value I′ to the control unit 11.

The control unit 11 can calculate the power consumption W1 of the electric appliance load 3 in operation mode T1 according to the current value I and the source voltage (a given value). The power consumption W1 can be saved in the power consumption memory unit 14. The control unit 11 can calculate the power consumption WHon of the electric appliance load 3 operated in operation mode T1 according to the power consumption W1 and the usage time. Besides, the power rate or the carbon dioxide emissions can be further calculated. These values can also be saved in the power consumption memory unit 14. The calculation of power usage cost is power (KW) multiplied by time to get electrical energy (KWH, thousand watts per hour), and then multiplied by charging rate. The calculation of carbon dioxide emissions is electrical energy (KWH) multiplied by carbon dioxide coefficient. A break loop status signal generating circuit 15 is connected to power supply loop L for generating a break loop status signal S2 to the control unit 11 when the power supply loop L is off.

The break loop status signal generating circuit 15 further comprises a loop control unit 151 for generating a loop control signal S3, so as to control the break loop status signal generating circuit 15 to generate break loop status signal S2 to the control unit 11. Wherein, the loop control unit 151 can be a manual operation unit 151a, a time counter 151b, an infrared body sensor (PIR) 151c, or a remote controller 151d (such as infrared remote controller or RF remote controller).

When the control unit 11 receives the break loop status signal S2 generated from the break loop status signal generating circuit 15, the control unit 11 calculates the saved power WHoff of electric appliance load 3 in power saving mode T2 according to the power consumption W1 and the lasting time after receiving the break loop status signal S2. The control unit 11 can further calculate power saving cost and reduced carbon dioxide emission according to the saved power WHoff.

The present invention further comprises a display unit 16, which is connected to the control unit 11 for displaying the power consumption WHon and the saved power WHoff, and power cost, reduced carbon dioxide emission both in operation mode T1 and power saving mode T2.

The present invention further comprises a voltage measuring circuit 17 including a voltage divider 171 and an analog to digital converter 172. The voltage divider 171 has two voltage dividing resistances 171a, 171b connected in series and then connected in parallel to the power supply loop L.

The voltage measuring circuit 17 can accurately measure the voltage value of the electric appliance load 3 supplied from the power supply 2. The analog to digital circuit 172 can convert it into a digital type voltage value and transmit the digital type voltage value to the control unit 11. The roughly calculated power (W) would be voltage value (V) multiplied by current value (A), while the accurate calculation should be voltage value (V) multiplied by current value (A) and further multiplied by power factor. According to the measuring voltage and current value, the control unit 11 can calculate the power factor for accurate power calculation. Besides, with the addition of the voltage measuring circuit 17, the voltage value and current value can be sampled at the same time, so that the control unit 11 can accurately calculate the power (W).

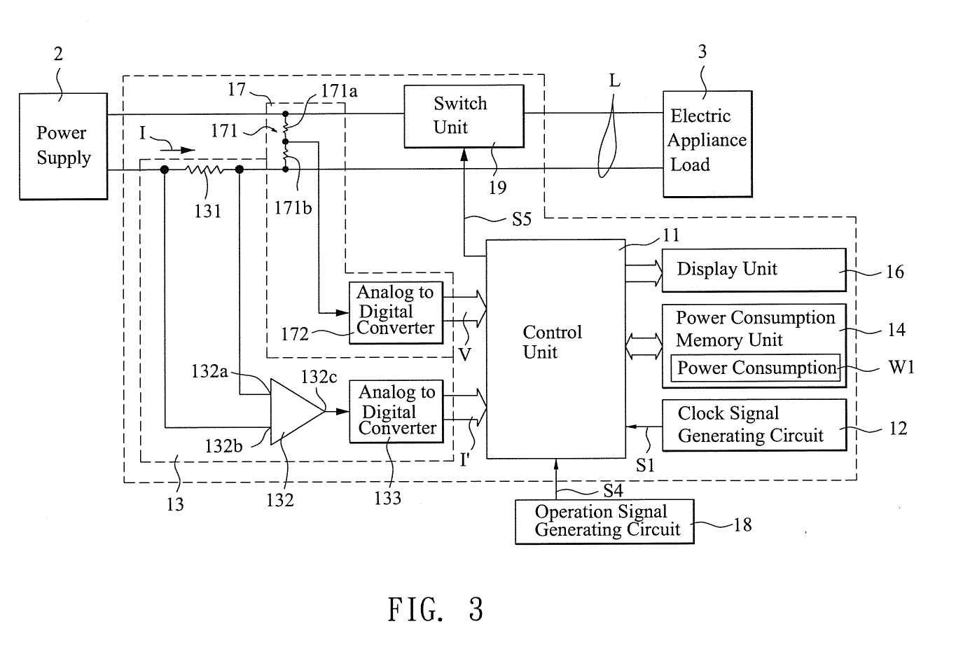

FIG. 3 shows a circuit diagram of the second embodiment in the present invention. In this embodiment, most elements are the same with that in the first embodiment. The only difference is that an operation signal generating circuit 18 is connected to the control unit 11 for generating a break loop operation signal S4 to the control unit 11. The operation signal generating circuit 18 can be a manual operation unit, a time counter, an infrared body sensor, or a remote controller.

When the control unit 11 receives the break loop operation signal S4, it generates a break loop control signal S5 to turn off the switch unit 19 connected to the power supply loop L to be open loop. As described in the first embodiment, the control unit 11 can calculate the saved power WHoff of the electric appliance load 3 in power saving mode T2 according to the power consumption W1 and the lasting time after receiving the break loop operation signal S4. The control unit 11 can further calculate power saving cost and reduced carbon dioxide emission according to the saved power WHoff.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A saved power measuring circuit for measuring saved power of an electric appliance load in power saving mode, the load being connected to a power supply via a power supply loop and being operated in operation mode or in power saving mode, the saved power measuring circuit comprising:
a control unit;
a clock signal generating circuit connected to the control unit for generating a clock signal to the control unit;
a power consumption measuring circuit connected to the power supply loop for measuring the power consumption of the electric appliance load operated in operation mode;
a power consumption memory unit connected to the control unit for memorizing the power consumption; and
a break loop status signal generating circuit connected to the power supply loop for generating a break loop status signal to the control unit when the power supply loop is off;
wherein when the control unit receives the break loop status signal generated from the break loop status signal generating circuit, the control unit calculates saved power of the electric appliance load in power saving mode according to the power consumption and the lasting time after receiving the break loop status signal.

2. The saved power measuring circuit as claimed in claim 1 further comprising a display unit connected to the control unit for displaying the consumption power or the saved power.

3. The saved power measuring circuit as claimed in claim 1, wherein the power consumption measuring circuit comprises:
a current sensor connected in series to the power supply loop;
a current amplifier including two input terminals connected to two terminals of the current sensor respectively for generating an analog current signal in an output terminal of the current amplifier; and
an analog to digital converter, which receives the analog current signal generated from the current amplifier, and transforms the analog current signal into a digital type current value and transmits the digital type current value to the control unit.

4. The saved power measuring circuit as claimed in claim 1, wherein the break loop status signal generating circuit further comprises a loop control unit to generate a loop control signal for controlling the break loop status signal generating circuit to transmit the break loop status signal to the control unit.

5. The saved power measuring circuit as claimed in claim 4, wherein the loop control unit is a manual operation unit, a time counter, an infrared body sensor, or a remote controller.

6. The saved power measuring circuit as claimed in claim 1, further comprising a voltage measuring circuit for measuring voltage of the electrical appliance load supplied by the power supply, the voltage measuring circuit comprising:
a voltage divider connected in parallel to the power supply loop; and
an analog to digital converter connected to the voltage divider for generating a digital type voltage signal to the control unit.

7. A saved power measuring circuit for measuring saved power of an electric appliance load in power saving mode, the load being connected to a power supply via a power supply loop and being operated in operation mode or in power saving mode, the saved power measuring circuit comprising:
a control unit;
a clock signal generating circuit connected to the control unit for generating a clock signal to the control unit;
a power consumption measuring circuit connected to the power supply loop for measuring the power consumption of the electric appliance load operated in operation mode;
a power consumption memory unit connected to the control unit for memorizing the power consumption;
a switch unit connected to the power supply loop; and
a operation signal generating circuit connected to the control unit, the operation signal generating circuit in operation generating a break loop operation signal to the control unit to control the switch unit in open loop status;
wherein when the control unit receives the break loop operation signal generated from the operation signal generating circuit, the control unit calculates saved power of the electric appliance load in power saving mode according to the power consumption and the lasting time after receiving the break loop operation signal.

8. The saved power measuring circuit as claimed in claim 7, further comprising a display unit connected to the control unit for displaying the power consumption or the saved power.

9. The saved power measuring circuit as claimed in claim 7, wherein the power consumption measuring circuit comprises:
a current sensor connected in series to the power supply loop;
a current amplifier including two input terminals connected to two terminals of the current sensor for generating an analog current signal in an output terminal of the current amplifier; and
an analog to digital converter, which receives the analog current signal generated from the current amplifier, and transforms the analog current signal into a digital type current value and transmits the digital type current value to the control unit.

10. The saved power measuring circuit as claimed in claim 7, wherein the operation signal generating circuit is a manual operation unit, a time counter, an infrared body sensor, or a remote controller.

11. The saved power measuring circuit as claimed in claim 7, further comprising a voltage measuring circuit for measuring voltage of the electrical appliance load supplied by the power supply, the voltage measuring circuit comprising:
a voltage divider connected in parallel to the power supply loop; and
an analog to digital converter connected to the voltage divider for generating a digital type voltage signal to the control unit.
